(19) United States
(12) Patent Application Publication
(10) Pub. No.: US 2026/0074508 A1
(43) Pub. Date: Mar. 12, 2026

(54) HIGH POWER SWITCHED SHUNT CAPACITOR ARCHITECTURES

(71) Applicant: Applied Materials, Inc., Santa Clara, CA (US)

(72) Inventors: CHRISTOPHER OWEN, Chandler, AZ (US); DAVID COUMOU, Webster, NY (US)

(21) Appl. No.: 19/195,646

(22) Filed: Apr. 30, 2025

Related U.S. Application Data
(60) Provisional application No. 63/692,640, filed on Sep. 9, 2024.

(51) Int. Cl. H02H 7/04; H01J 37/32; H02H 9/02

(52) U.S. Cl. CPC H02H 7/04; H01J 37/32183; H02H 9/02

(57) ABSTRACT

Embodiments described herein relate to an apparatus that includes a first trace, a capacitor electrically coupled to the first trace, and a balanced transformer electrically coupled to the capacitor. In an embodiment, a first transistor and a first diode are electrically coupled to a first inductor of the balanced transformer, and a second transistor and a second diode are electrically coupled to a second inductor of the balanced transformer.

### CROSS-REFERENCE TO RELATED APPLICATIONS

This application claims the benefit of U.S. Provisional Application No. 63/692,640, filed on Sep. 9, 2024, the entire contents of which are hereby incorporated by reference herein.

### BACKGROUND

### 1) Field

Embodiments of the present disclosure pertain to the field of plasma systems that include a multi-stage solid state impedance match.

### 2) Description of Related Art

In plasma processing tools (e.g., plasma etching chambers, plasma deposition chambers, plasma treatment chambers, etc.), precise control of the source power delivered to the chamber is needed to control the efficiency for the plasma system and prevent damage from reflected power back to the power source. Impedance matching is one parameter that is useful for controlling the power delivered to the chamber. For example, an impedance match is used to match the impedance of the power delivery system to the load impedance within the chamber.

Existing impedance match solutions include electro-mechanical devices and solid-state devices. Electro-mechanical devices are useful for high power applications, but they do not allow for rapid adjustments due to the use of a mechanical motor that is orders of magnitude slower than the ion transition rates across a plasma sheath. Solid state devices provide improved speed but are limited in voltage and/or current handling capability. Solid state devices also suffer from poor resolution.

### SUMMARY

Embodiments described herein relate to an apparatus that includes a first trace, a capacitor electrically coupled to the first trace, and a balanced transformer electrically coupled to the capacitor. In an embodiment, a first transistor and a first diode are electrically coupled to a first inductor of the balanced transformer, and a second transistor and a second diode are electrically coupled to a second inductor of the balanced transformer.

Embodiments described herein relate to an apparatus that includes a board and an electrically conductive trace on the board. In an embodiment, the apparatus further includes a plurality of switched shunt capacitors that are electrically coupled to the trace. In an embodiment, the plurality of switched shunt capacitors include a plurality of different capacitance values, and each of the plurality of switched shunt capacitors includes a capacitor, a transformer electrically coupled to the capacitor, and a transistor electrically coupled to the transformer. In an embodiment, the transistor has a bandgap that is 1.5 eV or higher.

Embodiments described herein relate to an apparatus that includes a first impedance match stage that includes a solid state varactor and a first switched shunt capacitor bank. In an embodiment, the first switched shunt capacitor bank includes a first plurality of individually controllable switched shunt capacitors. In an embodiment, the apparatus further includes a second impedance match stage that is electrically coupled to the first impedance match stage. In an embodiment, the second impedance match stage includes a second switch shunt capacitor bank that includes a second plurality of individually controllable switched shunt capacitors. In an embodiment, each of the first plurality and the second plurality of individually controllable switched shunt capacitors includes a capacitor, a transformer that is electrically coupled to the capacitor, and a transistor electrically coupled to the transformer, where the transistor has a bandgap that is 1.5 eV or higher.

### BRIEF DESCRIPTION OF THE DRAWINGS

FIG. 1A is a schematic illustration of a multi-stage match that includes banks of switched shunt capacitors that are controlled by high bandgap transistor devices, in accordance with an embodiment.

FIG. 1B is a schematic illustration of a multi-stage match that includes banks of switched shunt capacitors that are controlled by high bandgap transistor devices that include a sensor at a power output of the match, in accordance with an embodiment.

FIG. 1C is a schematic illustration of a plasma processing tool that comprises a power generator, a multi-stage solid state impedance match, and a plasma chamber, in accordance with an embodiment.

FIG. 2A is a schematic illustration of a second stage of an impedance match with a pair of capacitor banks, in accordance with an embodiment.

FIG. 2B is a schematic illustration of a first stage of an impedance match with a set of three capacitor banks, in accordance with an embodiment.

FIG. 2C is a schematic diagram of a capacitor bank that may be used in any of the stages of an impedance match, in accordance with various embodiments.

FIG. 2D is a circuit diagram of an individual switched shunt capacitor that is controlled by a high bandgap transistor, in accordance with an embodiment.

FIG. 2E is a circuit diagram of an individual switched shunt capacitor that is controlled by a pair of transistors arranged in a half-bridge configuration, in accordance with an embodiment.

FIG. 3A is a circuit diagram of a balanced switched shunt capacitor circuit with high bandgap transistors, in accordance with an embodiment.

FIG. 3B is a circuit diagram of a balanced switch shunt capacitor circuit with high bandgap transistors with diodes in parallel to reduce RF losses, in accordance with an embodiment.

FIG. 3C is a circuit diagram of a balanced switched shunt capacitor circuit with a pair of switched shunt capacitors with half-bridge configurations, in accordance with an embodiment.

FIG. 3D is a circuit diagram of a non-balanced switched shunt capacitor circuit with high bandgap transistors, in accordance with an embodiment.

FIG. 3E is a circuit diagram of a non-balanced switched shunt capacitor circuit without a transformer, in accordance with an embodiment.

FIG. 3F is a circuit diagram of a non-balanced switched shunt capacitor with a half-bridge configuration, in accordance with an embodiment.

FIG. 4 is a schematic illustration of a first stage of a match with an LC component to reduce the impedance, in accordance with an embodiment.

FIG. 5A is a circuit diagram of a switched shunt capacitor circuit with an impedance transformer, in accordance with an embodiment.

FIG. 5B is a circuit diagram of a balanced switched shunt capacitor circuit with a balanced transformer, in accordance with an embodiment.

FIG. 6 is an illustration of a block diagram of an exemplary computer system that may be used in conjunction with a processing tool, in accordance with an embodiment.

### DETAILED DESCRIPTION

Plasma systems that include a multi-stage solid state impedance match are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, impedance matches provide the control that enables efficient power delivery to plasma processing tools (e.g., plasma etching chambers, plasma deposition chambers, plasma treatment chambers, etc.). In order to provide the high switching speed needed for many plasma processes, solid state impedance matches have become a popular option. However, the low voltage and/or current handling capability and poor resolution of existing solid-state options renders such systems not suitable for high power environments.

Accordingly, embodiments disclosed herein may include solid state impedance matches that are based on high bandgap transistor devices. For example, high bandgap transistors (also sometimes referred to as wide bandgap transistors) may have a bandgap in the range of approximately 1.5 eV to approximately 4.0 eV or higher. In a particular embodiment, silicon carbide (SiC) transistors may be used in order to switch capacitors on and off in order to modify an impedance of the power delivery network. SiC transistor devices provide low RDSon, low parasitic capacitances (Coss), and may include VA ratings suitable for use in high-power RF networks. While SiC transistors are included as one option herein, it is to be appreciated that any suitable high bandgap transistor may be used, such as a GaN transistor, other III-V group semiconductor transistors, or the like. These high bandgap transistors enable the use of a broad capacitance range with optimized switching characteristics and faster stabilization of plasma generation to achieve high performance and through a cost effective solution.

In some instances, a limitation for DC bias voltages used to vary the capacitance of a cell arrangement of diodes is the rise time of the DC power supply. The current draw for the DC power is a function of the rise time. As such, reverse biasing of diodes may need a low current in some of the embodiments disclosed herein. This allows for a DC power rise time that is approximately 10 μs or less or approximately 1.0 μs or less. Such fast switching speeds may lead to significantly expanded process regimes for the plasma processing tool. The fast switching may also provide new tool capabilities for the control of plasma loads in the semiconductor industry. Faster switching times also speed up process times and reduces the total energy consumed by the process.

In an embodiment, the solid-state match may comprise a multi-stage matching network. In some embodiments, the multi-stage matching network may include a first matching network and a second matching network. In some instances, cascaded stages are implemented to adjust impedance transformation and coupling between stages for optimal minimization of losses while maximizing power efficiency by tailoring parasitic coupling and resistive losses from solid-state devices. Though, it is to be appreciated that embodiments disclosed herein may also be practiced with a single stage. In an embodiment, the solid-state impedance tuning system may be integrated with an RF power amplifier for unified power compensation and impedance control. This allows for optimal load power control for plasma stability through a wide dynamic impedance variation during plasma ignition and multi-rate pulsing. In some embodiments, the match may also provide harmonic attenuation. This allows for a reduction in the complexity of an RF generator harmonic filter. Additionally, high Q components can be used. This allows for greater reduction in RF losses, which is particularly beneficial for low plasma load impedances.

In an embodiment, switched shunt capacitors described herein may be biased by a high voltage power source. The high voltage bias is used to prevent conduction of the transistor body diode when the RF waveform goes negative. Also, the high voltage bias is used to bias the drain voltage to a point where the Coss is low and below the maximum voltage rating of the transistor for long term reliability. With high voltage switching, the shunt switched capacitor transistor provides a faster rise time. As such, a faster impedance switching is provided, and power losses are minimized within the impedance match. High voltage switching may also reduce transients on the RF power waveform.

In order to simplify the construction of the impedance match systems, some embodiments may include a switched shunt capacitor topology that does not require a high voltage DC bias power supply. As such, fewer components are necessary for the design of each switched shunt capacitor and costs, size, and complexity of the switched shunt capacitor may be reduced. Further, such embodiments allow for compatibility with high power RF generators, such as those that have output powers of approximately 3kW or more or approximately 10kW or more. The removal of the high voltage DC bias power supply may be enabled through the inclusion of a transformer into the switched shunt capacitor circuitry. The use of a transformer also provides greater flexibility in choosing the transistor characteristics, such as the Rdson and Coss characteristics. As such, the capacitor quality (Q) factor may be as high as possible when switched on while also having minimum leakage capacitance when the transistor is switched off. High Q factors ensure that as much power as possible is delivered to the plasma load. This may be particularly useful in low load impedance conditions. Embodiments may also provide a balanced topology so that the RF waveforms are symmetrical and have a lower second harmonic.

Embodiments disclosed herein may also allow for improved compatibility with high output power RF generators (e.g., 3 kW or more or 10 kW or more). For example, topologies described herein allow for the impedance match system to handle higher peak RF voltages. Ideally, the topologies described herein approach optimal performance to deliver a maximum RF power to the load with the highest efficiency.

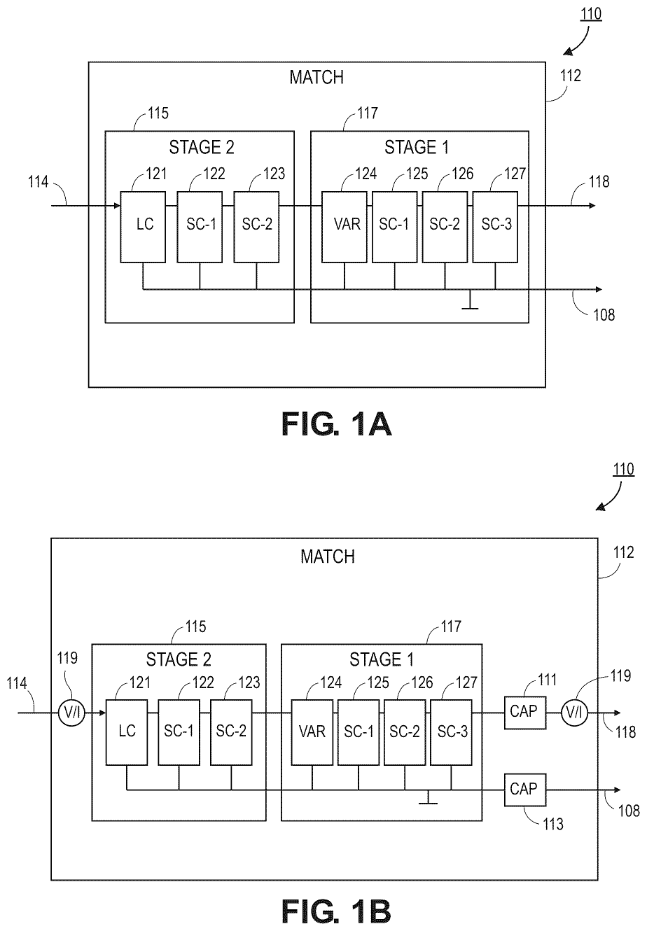

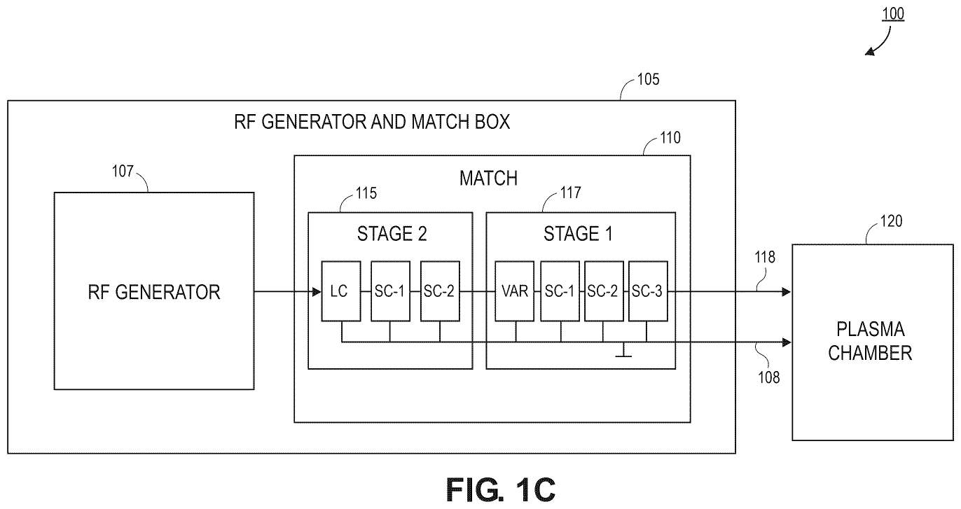

Referring now to FIG. 1A, a schematic illustration of an impedance match 110 is shown, in accordance with an embodiment. In an embodiment, the impedance match 110 may be an RF impedance match. For example, an RF generator (not shown) may provide RF power to an input 114 of the impedance match 110. Similarly, impedance matched power may exit the impedance match 110 at output 118. A ground line 108 may also be coupled to the impedance match 110.

In an embodiment, the impedance match 110 may comprise a board 112 for mounting one or more impedance matching stages. For example, a second stage 115 may be provided at the input 114, and a first stage 117 may be provided at the output 118. In the illustrated embodiment, the first stage 117 and the second stage 115 are provided on separate boards. Though, the first stage 117 and the second stage 115 may also be on the same board in some embodiments. Additionally, while two stages 117 and 115 are shown in FIG. 1A, it is to be appreciated that three or more stages may also be used in some embodiments. That is, the number of stages is scalable to fit the needs of a desired application.

In an embodiment, the second stage 115 may include an LC module 121 (e.g., a circuit element comprising one or more capacitors and one or more inductors). The LC module 121 may feed into a first switched shunt capacitor bank 122 and a second switched shunt capacitor bank 123. While shown in FIG. 1A, other embodiments may omit the LC module 121. In an embodiment, the switched shunt capacitor banks 122 and 123 may each comprise a plurality of switched shunt capacitors that are each turned on/off through the use of high bandgap transistors, such as a SiC transistor or the like. A more detailed explanation of the switched shunt capacitors will be provided in greater detail herein.

While a first switched shunt capacitor bank 122 and a second switched shunt capacitor bank 123 are shown in FIG. 1A, it is to be appreciated that any number of switched shunt capacitor banks may be used in the second stage 115. Each of the switched shunt capacitor banks 122 or 123 may comprise any number of high bandgap capacitors in order to provide a desired level of capacitance along the RF path between the input 114 and the output 118. The individual capacitors within a single capacitor bank may include different capacitance values or two or more of the individual capacitors within a single capacitor bank may have the same capacitance value.

In an embodiment, the second stage 115 may be used to convert an impedance of the power delivery network to match an impedance of an RF generator (not shown). For example, the impedance of the RF generator may be approximately 50 Ohms. In an embodiment, the first stage 117 may be used to match the impedance of the load coupled to the power delivery network (e.g., a plasma within a chamber coupled to the impedance match 110).

In an embodiment, the first stage 117 may be electrically coupled to the second stage 115. The first stage 117 may comprise a varactor 124 and a plurality of additional switched shunt capacitor banks 125, 126, and 127. The varactor 124 may allow for an analog (i.e., substantially continuous) control of the impedance before reaching the additional switched shunt capacitor banks 125, 126, and 127. While shown as being within the first stage 117, other embodiments may include inserting the varactor 124 in the second stage 115 (e.g., before the switch shunt capacitor banks 122 and 123) or as a discrete system between the first stage 117 and the second stage 115. In an embodiment, the varactor 124 may also be implemented as a solid state component. In such an embodiment, the varactor 124 may comprise high bandgap transistors, such as SiC transistors.

In an embodiment, the first stage 117 may be used to control an impedance from between approximately 0.2 Ohms to approximately 10 Ohms in order to match a load impedance within a plasma chamber that is electrically coupled to the output 118. Further, the first stage 117 may be used to transfer the whole range of complex load impedances to a purely resistive impedance for the desired range (e.g., approximately 0.2 Ohms to approximately 10 Ohms).

While three different switched shunt capacitor banks 125, 126, and 127 are shown in FIG. 1A, it is to be appreciated that any number of switched shunt capacitor banks may be used in the first stage 117. Each of the switched shunt capacitor banks 125, 126, and 127 may comprise any number of high bandgap capacitors in order to provide a desired level of capacitance along the RF path between the input 114 and the output 118. The individual capacitors within a single capacitor bank may include different capacitance values or two or more of the individual capacitors within a single capacitor bank may have the same capacitance value.

Referring now to FIG. 1B, a plan view illustration of an impedance match 110 is shown, in accordance with an additional embodiment. In an embodiment, the impedance match 110 in FIG. 1B may be similar to the impedance match 110 in FIG. 1A, with the addition of capacitors 111 and 113. The capacitors 111 and 113 may by extremely high Q components in order to improve performance of the match 110 in some embodiments. For example, the capacitors 111 and 113 may be vacuum capacitors. In some embodiments, one or both of capacitors 111 or 113 may be optional. Additionally, an RF sensor 119 (e.g., a voltage/current (V/I) sensor) may be provided on the impedance match 110. Particularly, a pair of RF sensors 119 are provided in FIG. 1B. A first RF sensor 119 may be provided before the second stage 115 at the input 114, and a second RF sensor 119 may be provided after the first stage 117 at the output 118. In an embodiment, the RF sensors 119 may be used in order to monitor the power delivered to the plasma chamber through the impedance match 110. This can be used for control purposes and/or for an indication of when a safe operating area (SOA) is exceeded for the impedance match 110 and/or the plasma processing tool in general.

Referring now to FIG. 1C, a schematic diagram of a plasma processing system 100 is shown, in accordance with an embodiment. In an embodiment, the plasma processing system 100 may comprise an RF generator and match box 105. The box 105 may be a housing and/or enclosure that integrates an RF generator 107 and the match 110 into a single system. The RF generator 107 may generate RF power that is delivered to a plasma chamber 120 through the match 110. In an embodiment, the match 110 may be similar to the match 110 described with respect to FIG. 1A or 1B. For example, the match 110 may comprise a plurality of stages (e.g., a first stage 117 and a second stage 115). Each of the stages 117 and 115 may comprise a plurality of switched shunt capacitor banks.

In an embodiment, the plasma chamber 120 may be chamber capable of supporting a plasma. For example, the plasma chamber 120 may be a low-pressure chamber, such as a vacuum chamber. In an embodiment, the plasma chamber 120 may include a plasma deposition chamber, a plasma etching chamber, a plasma treatment chamber, or the like. The output 118 may deliver RF power to the plasma chamber 120 in order to ignite and/or sustain a plasma within the plasma chamber 120. A ground line 108 may also be coupled between the plasma chamber 120 and the match 110.

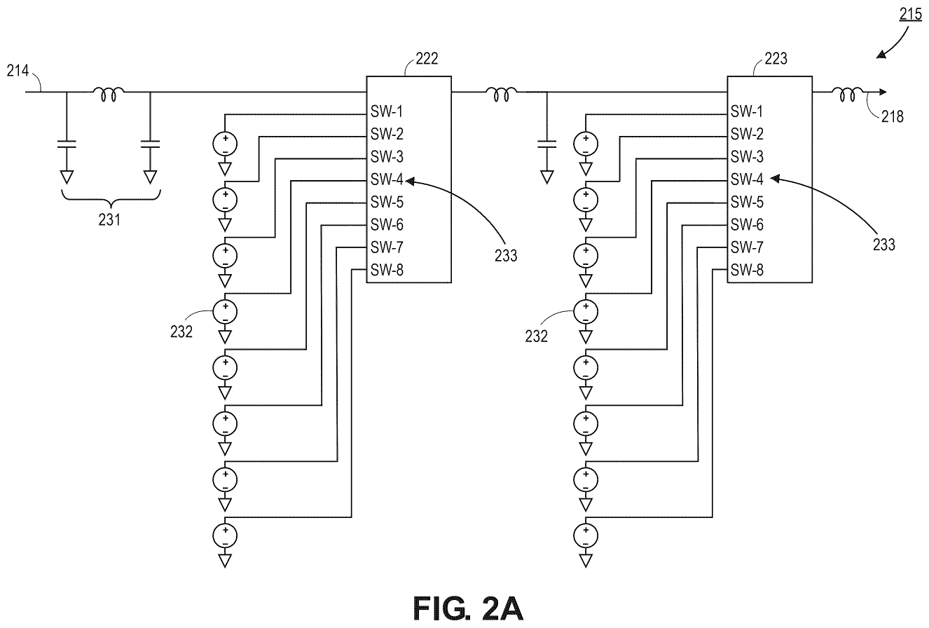

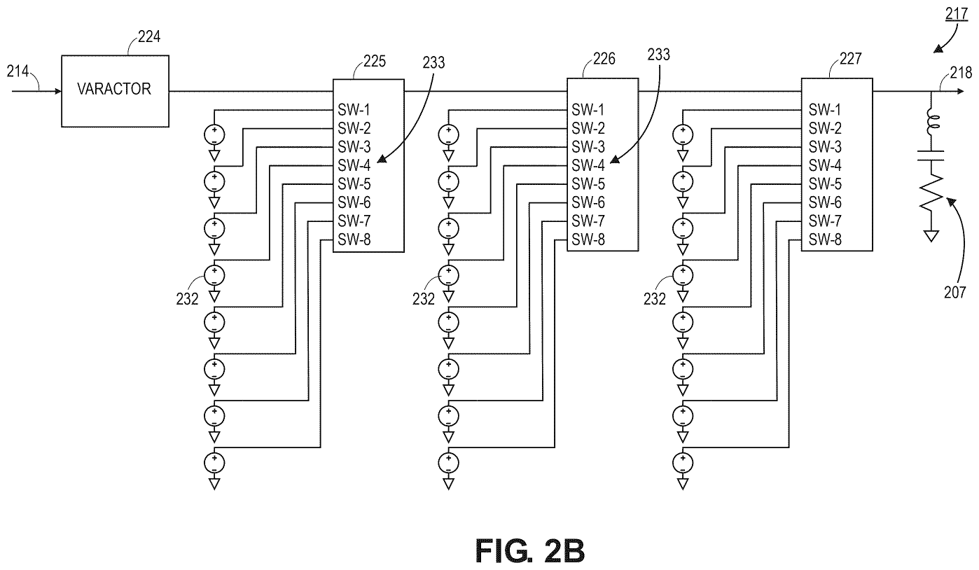

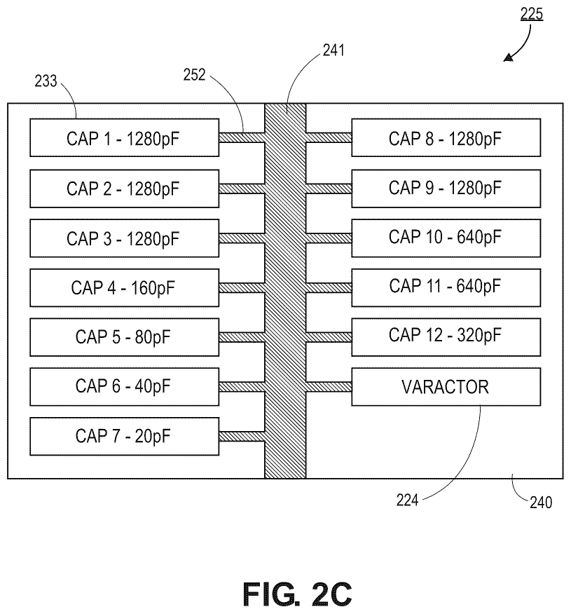

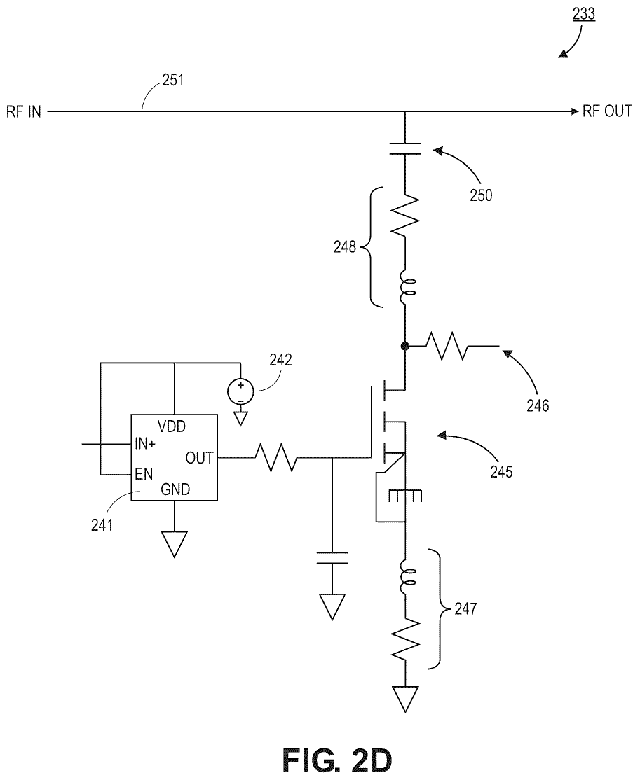

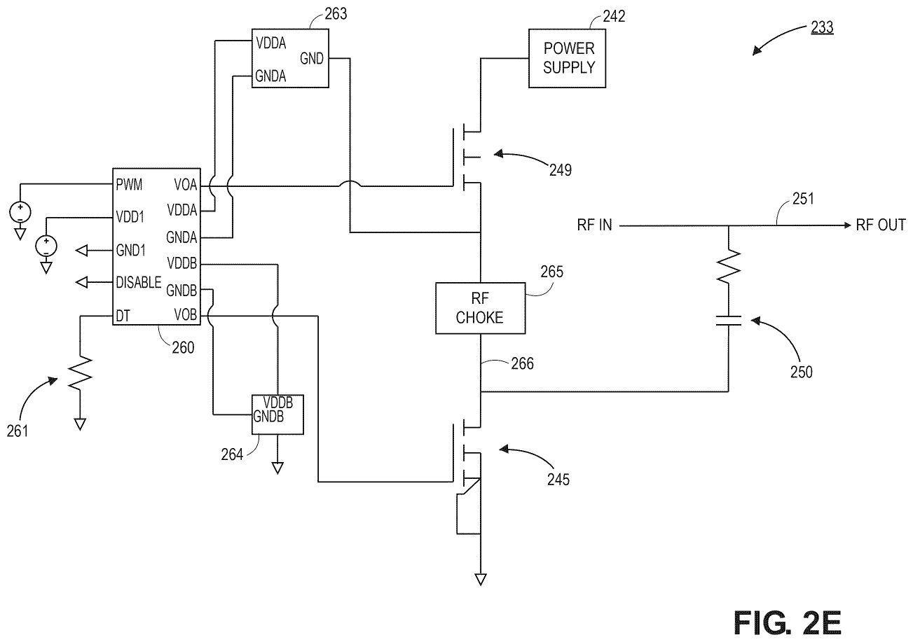

Referring now to FIGS. 2A and 2B, schematic illustrations of different stages of a multi-stage match are shown, in accordance with an embodiment. Referring now to FIG. 2A, a second stage 215 is shown, in accordance with an embodiment. As shown, an input 214 to the second stage 215 may enter an LC module 231. In an embodiment, the LC module 231 may be a circuit element comprising one or more capacitors and one or more inductors. Though, in other embodiments, the LC module 231 may be omitted. In an embodiment, the second stage 215 may continue along the main RF path to a first switched shunt capacitor bank 222 and a second switched shunt capacitor bank 223 before reaching an output 218. In an embodiment, the capacitor banks 222 and 223 each include a plurality of individual switched shunt capacitors 233. The switched shunt capacitors 233 may each be coupled to a power source 232, such as a DC power source. A more detailed description of the circuitry for the switched shunt capacitors 233 and how they are turned on/off is provided in greater detail herein.

In the illustrated embodiment, the first capacitor bank 222 and the second capacitor bank 223 have the same number of switched shunt capacitors 233. Though, in other embodiments, the capacitor banks 222 and 223 may have a different number of switched shunt capacitors 233. While eight switched shunt capacitors 233 are shown in each capacitor bank 222 and 223, it is to be appreciated that each capacitor bank 222 and 223 may comprise one or more switched shunt capacitors 233. In an embodiment, each of the switched shunt capacitors 233 may have substantially the same electrical characteristics (e.g., capacitance, Q-value, etc.). In such an embodiment, switching on a desired number of switched shunt capacitors 233 within a capacitor bank 222 or 223 can provide a desired total capacitance to the second stage 215 that is an integer multiple of the capacitance of each switched shunt capacitors 233. In some embodiments, a more granular change in the total capacitance may be provided by including switched shunt capacitors with multiple different capacitances. For example, a first switched shunt capacitor 233 may have a capacitance C, a second switched shunt capacitor 233 may have a capacitance C/2, a third switched shunt capacitor 233 may have a capacitance C/4, a fourth switched shunt capacitor 233 may have a capacitance C/8, or the like. Accordingly, more granular control of the total capacitance can be provided to the second stage 215 of the impedance match.

Referring now to FIG. 2B, a schematic illustration of a first stage 217 of the match is shown, in accordance with an embodiment. In an embodiment, the input 214 may lead into a varactor 224. The varactor 224 may provide a more granular control (e.g., analog or substantially continuous control) of the impedance. The following components may include a third capacitor bank 225, a fourth capacitor bank 226, and a fifth capacitor bank 227. In an embodiment, each of the additional capacitor banks 225-227 may be similar to the capacitor banks 222 and 223 described with respect to FIG. 2B. For example, each capacitor bank 225-227 may comprise one or more switched shunt capacitors 233 that are powered by power sources 232 (e.g., a DC power source 232). While three capacitor banks 225-227 are shown, it is to be appreciated that any number capacitor banks 225-227 may be included in the first stage 217. In some embodiments, a grounded inductor (e.g., a shunt inductor) (not shown) may be provided at the output 218 after the capacitor bank 227 in order to neutralize leakage through the match when all of the capacitors 233 are switched off. In some embodiments a second harmonic trap circuit 207 may also be provided between the last capacitor bank 227 and the output 218. The second harmonic trap circuit 207 may be used to mitigate second harmonic levels within the system. This may occur because each of the switching transistors that control the capacitors 233 have different Coss capacitance depending on whether the instantaneous drain voltage is at a high voltage or a low voltage. As such, a sine wave picks up some second harmonic distortion at each switched capacitor when the associated transistor is off. In the embodiment shown in FIG. 2B, the second harmonic trap circuit 207 comprises a shunt LC notch.

Referring now to FIG. 2C, a plan view schematic illustration of a capacitor bank 225 is shown, in accordance with an embodiment. In an embodiment, the capacitor bank 225 may comprise a board 240, such as a printed circuit board (PCB) or the like. In an embodiment, a trace 251 (e.g., an RF trace) extends across the board 240. A plurality of capacitors 233 may be coupled to the board 240 and electrically coupled to the trace 251 by traces 252. The capacitors 233 may be discrete components (described in greater detail herein) that are mounted to the board 240 with any suitable mounting option suitable for electrically coupling the capacitors 233 to the board 240 (e.g., soldering, sockets, solder interconnects, etc.).

In an embodiment, the plurality of capacitors 233 may comprise one or more different capacitance values. For example, the capacitors 233 may have capacitance values equal to 2ⁿ x, where n starts at zero and increases by one for each capacitance level in order to provide a desired capacitance resolution for the capacitor bank, and x is greater than 0 pF. In the illustrated embodiment, x is equal to 20 pF and n starts at zero and goes up to six in order to provide seven different capacitance values that includes 20 pF, 40 pF, 80 pF, 160 pF, 320 pF, 640 pF, and 1280 pF. The number of capacitors 233 at each capacitance value may be tailored to provide desired total capacitance values for the capacitor bank. Though, it is to be appreciated that any collection of capacitors 233 with any desired capacitance values may be used in other embodiments.

In some embodiments, the capacitor bank 225 may also comprise a varactor 224. The inclusion of a varactor 224 may be used to provide even finer resolution for the overall capacitance of the capacitor bank 225 since the varactor 224 may provide a capacitance that can be changed in a substantially analog manner. In an embodiment, the varactor 224 may also comprise high bandgap transistors, such as any of those described in greater detail herein.

Referring now to FIG. 2D, a circuit diagram of an individual switched shunt capacitor 233 is shown, in accordance with an embodiment. In an embodiment, the switched shunt capacitor 233 may comprise a capacitor 250 that is coupled to a main RF trace 251. In an embodiment, the capacitor 250 is switched from on to off through the use of a transistor 245. In an embodiment, the transistor 245 may comprise a high bandgap transistor, such as one formed with SiC, GaN, other III-V group semiconductor transistors, or the like. For example, the transistor 245 may comprise a SiC MOSFET device. The power for the transistor 245 may be provided by a power supply 242 (e.g., a DC power supply 242) that is coupled to a PWM diver 241. In an embodiment, a high voltage bias branch 246 may be provided between the transistor 245 and the capacitor 250. The high voltage bias branch 246 may comprise a high voltage power source (not shown), such as a high voltage DC power source. In an embodiment, some parasitic elements 247 and 248 are illustrated in the circuit for illustration purposes.

Referring now to FIG. 2E, a circuit diagram of an individual switched shunt capacitor 233 is shown, in accordance with an additional embodiment. The switched shunt capacitor 233 in FIG. 2E may be driven with a half-bridge topology. For example, a pullup transistor 249 and a pulldown transistor 245 may be used to charge and discharge the capacitor 250. The pullup transistor 249 and the pulldown transistor 245 may be high bandgap transistors, such as SiC transistors, GaN transistors, other III-V group semiconductor transistors, or the like. The source of the pulldown transistor 245 may be coupled to ground, and the drain of the pullup transistor 249 may be coupled to a power supply 242. The power supply 242 may be a DC power supply.

In an embodiment, a source of the pullup transistor 249 may be electrically coupled to a drain of the pulldown transistor 245 by an electrical trace 266. An RF choke circuitry block 265 may be provided along the electrical trace 266. The RF choke circuitry block 265 may prevent RF propagation into the pullup transistor 249. The RF choke circuitry block 265 may include one or more RF filter circuits, inductors, and/or the like.

In an embodiment, the pullup transistor 249 and the pulldown transistor 245 may be driven by a half-bridge driver 260. The half-bridge driver 260 may have a resistor 261 coupled to the DT input to ensure that the pullup transistor 249 and the pulldown transistor 245 are not on at the same time. The resistor 261 may be chosen to provide a dead time that is approximately 0.5 μs or less.

In an embodiment, the half-bridge driver 260 may be coupled to a first power supply 263 for controlling the pullup transistor 249. That is, the first power supply 263 may be electrically coupled to the gate of the pullup transistor 249 through the half-bridge driver 260. The first power supply 263 may be held at an electrically floating voltage set by the power supply 242 (e.g., around 600V). Since the first power supply 263 is electrically floating, the first power supply 263 is capable of pulling up the voltage to block RF current from going into the pullup transistor 249. The half-bridge driver 260 may also be coupled to a second power supply 264 for controlling the pulldown transistor 245. That is, the second power supply 264 may be electrically coupled to the gate of the pulldown transistor 245 through the half-bridge driver 260. The half-bridge driver 260 allows for voltage to be applied to either the gate of the pullup transistor 249 (which allows power supply 242 to charge the capacitor 250) or to the gate of the pulldown transistor 245 (which allows the charge in the capacitor 250 to be drained to ground).

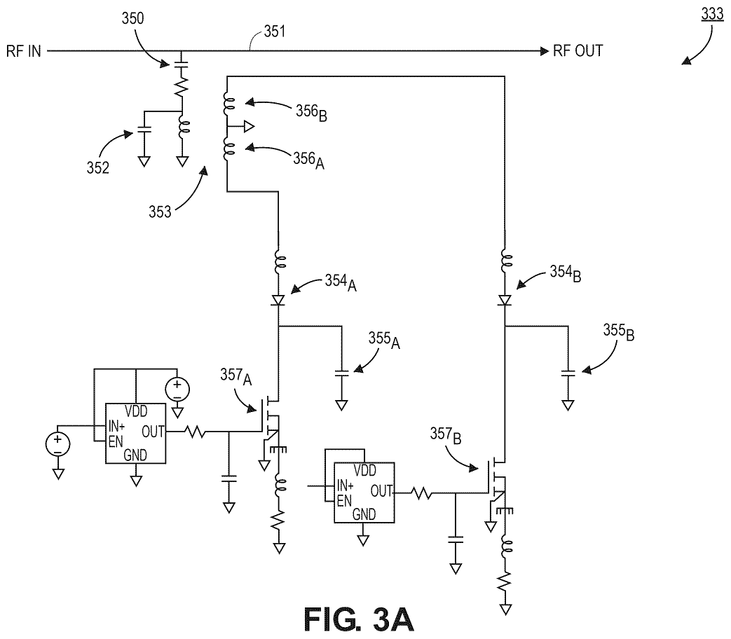

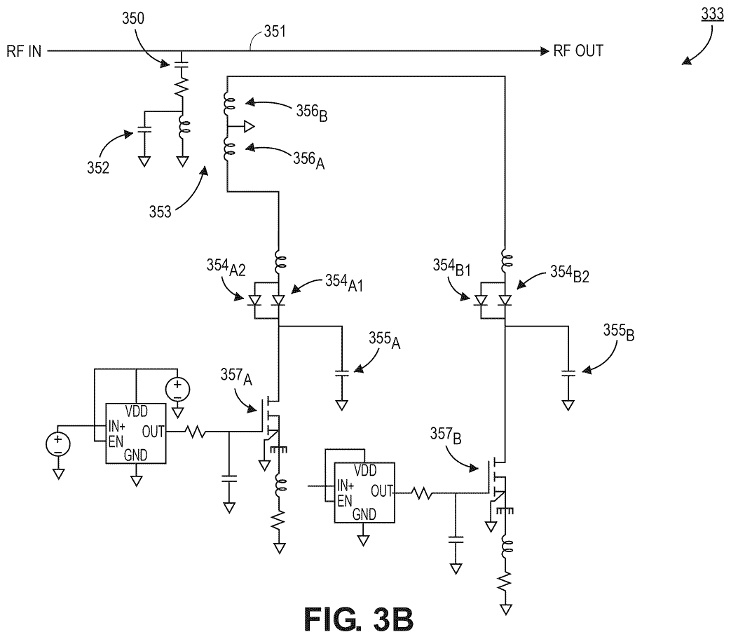

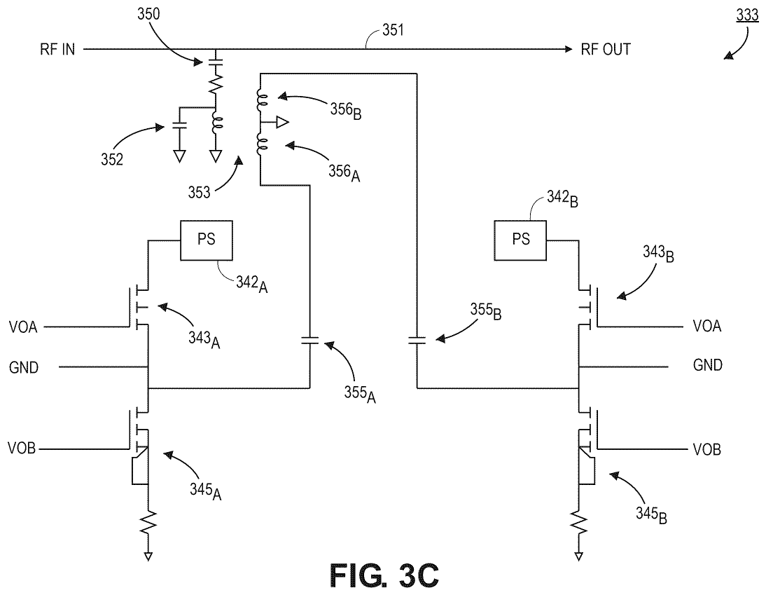

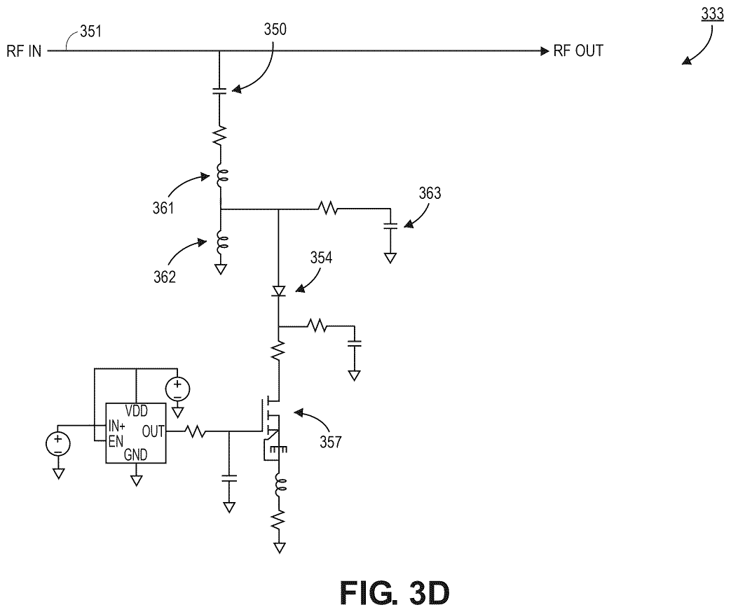

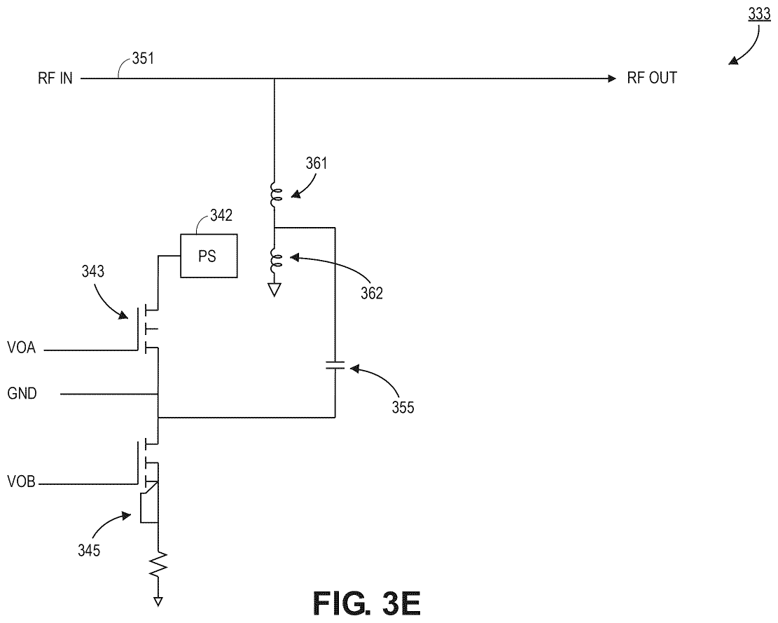

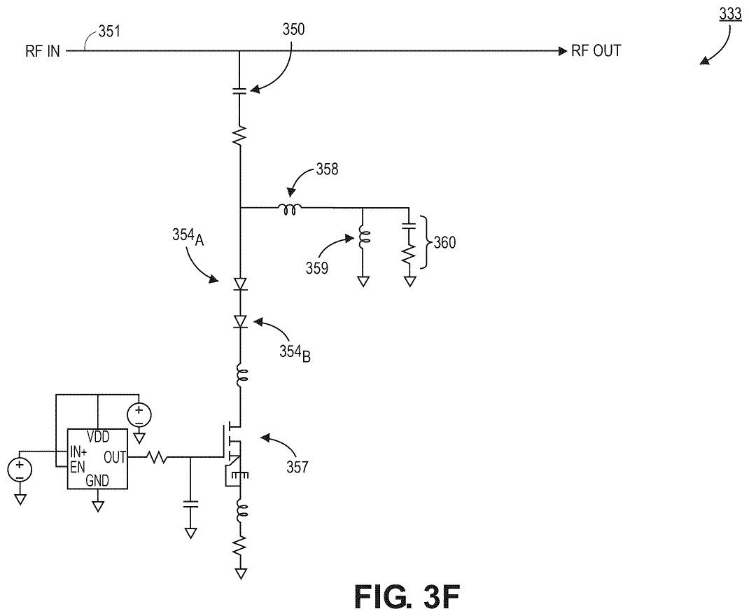

In FIG. 2D, the switched shunt capacitor 233 is shown as having an auto-bias branch 246. However, the use of a dedicated DC power source creates additional cost and complexity for the switch shunt capacitor 233. Accordingly, embodiments disclosed herein include topologies that allow for the removal of the dedicated DC power source along the auto-bias branch 246. Examples of such topologies are shown in FIG. 3A-3D.

Referring now to FIG. 3A, a circuit diagram of a switched shunt capacitor 333 that is coupled to a main RF line 351 is shown, in accordance with an embodiment. In an embodiment, the main capacitor 350 is a high Q RF capacitor. A balanced transformer 353 is electrically coupled to the main capacitor 350. For example, an inductor and capacitor 352 are electrically coupled to the main capacitor 350. The opposite side of the balanced transformer 353 may include a first inductor 356_{A} and a second inductor 356_{B}. The first inductor 356_{A} and the second inductor 356_{B} may be inductively coupled to the inductor that is electrically coupled to the main capacitor 350. In an embodiment, the capacitor 352 may be used to tune the balanced transformer 353 to ensure minimum off state RF current in the main capacitor 350.

In an embodiment, the balanced transformer 353 is used to transform the currents and voltages best suited for the switching components and to provide higher RF power capabilities. Capacitance values of the main capacitor 350 (e.g., from between approximately 5 pF to approximately 5,000 pF) may be switched depending on the RF power levels. Further, a balanced transformer 353 topology provides minimum second harmonic distortion.

In an embodiment, the balanced transformer 353 may be electrically coupled to a pair of transistors 357_{A} and 357_{B}. For example, the transistors 357_{A} and 357_{B} may be high bandgap transistors, such as SiC MOSFETs. In an embodiment, a diode 354_{A} may be electrically coupled between the transistor 357_{A} and the inductor 356_{A}, and a diode 354_{B} may be electrically coupled between the transistor 357_{B} and the inductor 356_{B}. In an embodiment, when the transistors 357_{A} and 357_{B} are turned fully on, the RF currents flow through the diodes 354_{A}, 354_{B} and the transistors 357_{A}, 357_{B} to ground so that the main capacitor 350 is switched on. When the transistors 357_{A} and 357_{B} are turned fully off, the RF current flows through the diodes 354_{A} and 354_{B} in order to charge capacitors 355_{A} and 355_{B}, respectively. The charging may include a charge up to several hundred volts in less than approximately 1.0 μs or less than approximately 0.5 μs. Meanwhile, the inductors 356_{A} and 356_{B} provide DC current return to allow the detectors to work.

In an embodiment, the high bias voltages stored on the capacitors 355_{A} and 355_{B} are sufficient to prevent the negative RF voltages from conducting through the body diodes of the transistors 357_{A} and 357_{B}. Therefore, the complete circuit ensures that the RF current flowing through the main capacitor 350 is close to zero when the main capacitor 350 is switched off.

Referring now to FIG. 3B, a circuit diagram of a switched shunt capacitor 333 that is coupled to a main RF line 351 is shown, in accordance with an embodiment. In an embodiment, the switched shunt capacitor 333 in FIG. 3B may be similar to the switched shunt capacitor 333 in FIG. 3A, with the exception of the diodes 354. Instead of a single diode 354 along each branch of the balanced topology, a plurality of diodes 354 are provided in parallel along each branch of the balanced topology. For example, diodes 354_{A1} and 354_{A2} are in parallel between the transistor 357_{A} and the inductor 356_{A}, and diodes 354_{B1} and 354_{B2} are in parallel between the transistor 357_{B} and the inductor 356_{B}. Though, it is to be appreciated that any number of diodes 354 may be added in parallel to improve performance. Such an embodiment is particularly useful for low load impedance conditions (e.g., 0.2 Ohms of an unlit plasma load from a 50 Ohm RF generator). That is, a key performance parameter for an RF match may be a measure of how much of the RF power is delivered to the load in such low impedance conditions. In some instances, the diodes 354 are the largest source of power loss and significantly impact the performance of the RF match. These loses may be mitigated by reducing the on resistance of the diodes 354. One way to reduce the on resistance is to add multiple diodes 354 in parallel.

Referring now to FIG. 3C, a circuit diagram of a switched shunt capacitor 333 that is coupled to a main RF line 351 is shown, in accordance with an additional embodiment. In an embodiment, the switched shunt capacitor 333 in FIG. 3C is similar to the switched shunt capacitor 333 in FIG. 3A, with the exception of the construction of the switch for the capacitors 355_{A} and 355_{B}. For example, each branch of the balanced transformer 353 may comprise a pullup transistor 343_{A} or 343_{B} and a pulldown transistor 345_{A} or 345_{B}. The pullup transistors 343_{A} and 343_{B} may each have drains that are coupled to power sources 342_{A} or 342_{B}. In the illustrated embodiments, the driving circuitry for the half-bridge configuration (e.g., the half-bridge driver) and additional floating power sources and/or the like are omitted for simplicity. However, it is to be appreciated that the half-bridge switches used in the switched shunt capacitor of 333 FIG. 3C may be similar to any of the half-bridge switched shunt capacitor configurations described in greater detail herein, such as the switched shunt capacitor 233 described with respect to FIG. 2E.

Referring now to FIG. 3D, a circuit diagram of a switched shunt capacitor 333 that is coupled to a main RF line 351 is shown, in accordance with an embodiment. In contrast to the embodiments shown in FIG. 3A-3C, the topology of the switched shunt capacitor 333 in FIG. 3D is a non-balanced design. In such an embodiment, an auto-transformer (e.g., inductors 361 and 362) are used instead of a balanced transformer. Such an embodiment allows for a reduction in complexity since fewer components are needed. For example, a single branch with a singled transistor 357 may be needed in some embodiments. In such an embodiment, a capacitor 363 may be used to ensure a minimum current in the main capacitor 350 is allowed when the transistor 357 is switched off.

Referring now to FIG. 3E, a circuit diagram of a switched shunt capacitor 333 that is coupled to a main RF line 351 is shown, in accordance with an additional embodiment. In an embodiment, the switched shunt capacitor 333 in FIG. 3E may be similar to the switched shunt capacitor 333 in FIG. 3D, with the exception of the switching architecture. For example, a half-bridge configuration with a pullup transistor 343, a pulldown transistor 345, and a capacitor 355 is coupled to the auto transformer (e.g., inductors 361 and 362). In an embodiment, the capacitor 355 is switched on and off by the pullup transistor 343 and the pulldown transistor 345 in order to add or subtract capacitance to the RF line 351. In an embodiment, the half-bridge configuration may be similar to any of the half-bridge switch configurations described in greater detail herein, such as half-bridge configuration of FIG. 2E.

Referring now to FIG. 3F, a circuit diagram of a switched shunt capacitor 333 that is coupled to a main line 351 is shown, in accordance with an additional embodiment. The switched shunt capacitor 333 in FIG. 3F removes the presence of lossy transformers. The removal of transformers may also allow for the removal of the associated heat sinking. Such a switched shunt capacitor 333 may operate through the use of one or more diodes 354_{A} and 354_{B} that are provided in series between the transistor 357 and the main capacitor 350. When the transistor 357 is switched off, the diodes 354_{A} and 354_{B} generate the high voltage at the drain of the transistor 357. The transistor 357 capacitance may hold the voltage up, and the diode current return is provided through the inductors 358 and 359 to ground. In an embodiment, a high impedance resonator circuit 360 formed from the inductor 359 and an adjacent capacitor set a desired resonance (e.g., 13.56 MHz) in order to further reduce RF losses. Such a circuit topology may have lower RF losses and good derating factors. The simplicity also leads to a compact size and reduced cost.

As described in greater detail above, the use of high bandgap MOSFET devices may allow for higher Vds voltage ratings. For example, voltage ratings for SiC MOSFET devices used in switched shunt capacitor circuits may be up to 3.3 kV. When using high voltage transistors, analysis is needed to determine which transistor and switching topology enables the highest match Q factor. This is because higher Q factors provide the highest RF power delivered to the lowest impedance loads (e.g., around 0.2 Ohms). One drawback of using high voltage transistors is that they typically include a higher Rdson and lower current capability. In order to avoid these issues, a plurality of high voltage transistors can be arranged in parallel to effectively reduce their combined Rdson and increase their combined current handling capability.

In FIG. 3A-3D, the capacitors 350 are controlled by a high bandgap transistors 357 with a configuration similar to the one shown in FIG. 2D. Though, it is to be appreciated that capacitors 350 may also be controlled by a pair of transistors using a half-bridge configuration, similar to the embodiment shown in FIG. 2E. That is, each of the capacitors 350 may be controlled by one or more pullup transistors and one or more pulldown transistors.

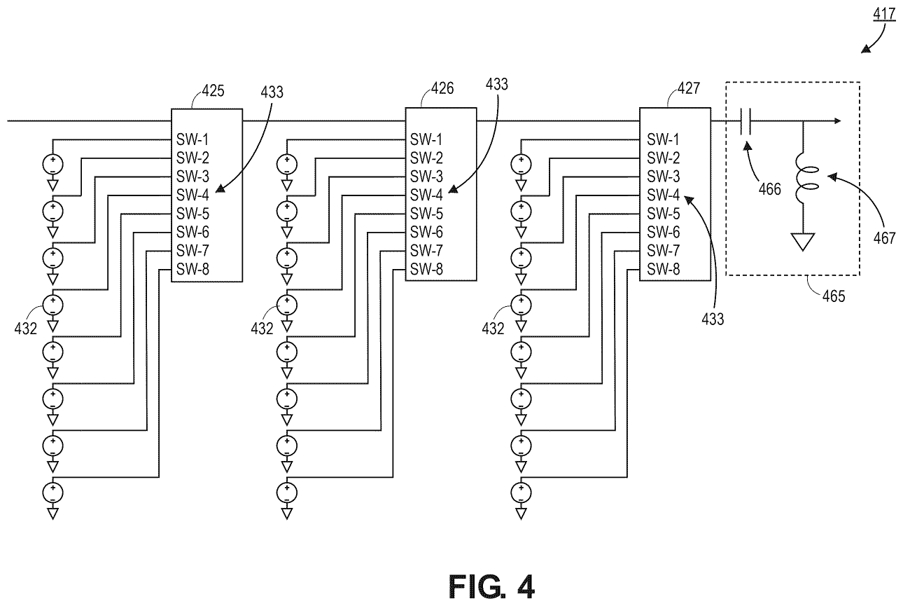

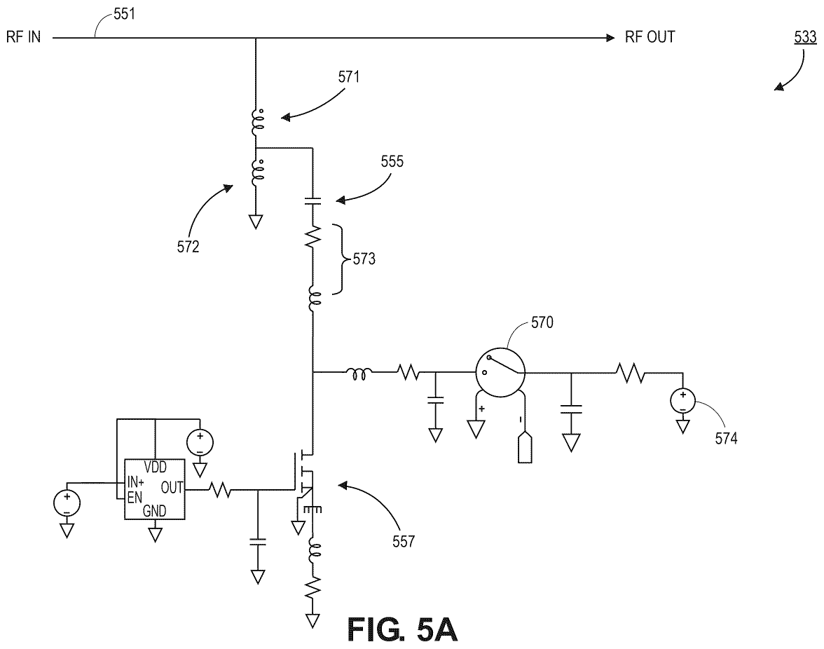

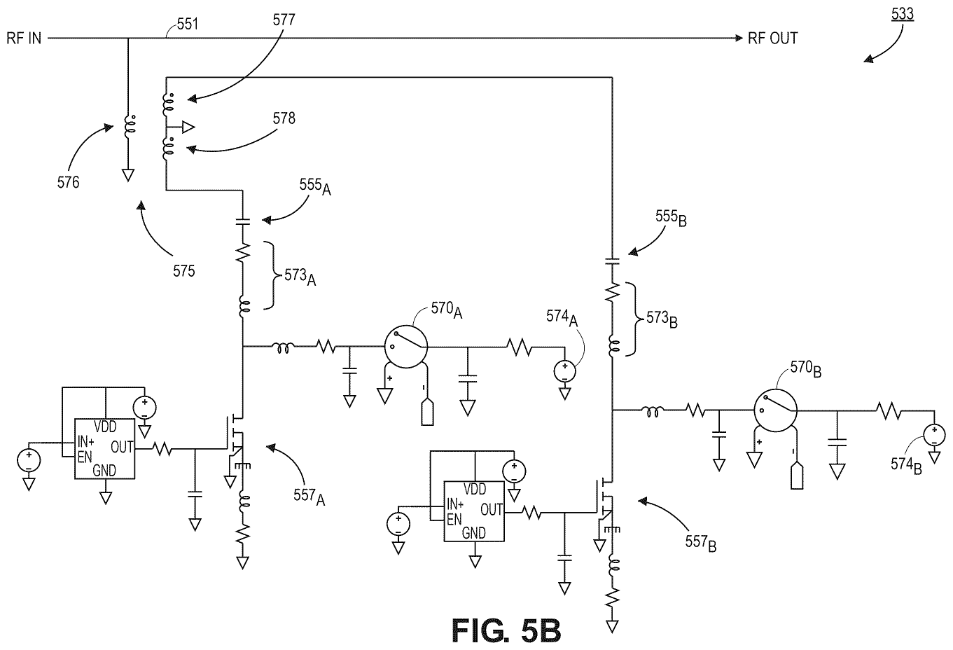

In addition to selecting components (e.g., transistors, capacitors, inductors, etc.) with the specifications to enable high Q factors, embodiments may include modifications and/or additions to the circuitry of the individual switched shunt capacitors and/or to the overall multi-stage match topology. Examples of such embodiments are shown in FIG. 4 and FIGS. 5A and 5B.

Referring now to FIG. 4, a schematic illustration of a first stage 417 of a multi-stage match is shown, in accordance with an embodiment. In an embodiment, the first stage 417 may comprise a plurality of capacitor banks 425, 426, and 427. Each capacitor bank 425-427 may comprise a plurality of switched shunt capacitors 433, and each switched shunt capacitor 433 may be electrically coupled to a power source 432, such as a DC power source. In an embodiment, the capacitor banks 425-427 may be similar to the capacitor banks 225-227 in FIG. 2B. The first stage 417 may also comprise a varactor (not shown) in some embodiments.

In an embodiment, the output of the third capacitor bank 427 may be electrically coupled to an LC module 465. The LC module 465 may comprise a capacitor 466 and an inductor 467. The LC module 465 may be used to reduce the impedance and peak voltage before the RF power reaches the plasma load. In some embodiments, the presence of the LC module 465 may require an increased switched shunt capacitance since the main RF path impedance is reduced by the LC module 465.

Referring now to FIG. 5A, a circuit diagram of a switched shunt capacitor 533 coupled to a main RF line 551 is shown, in accordance with an embodiment. In an embodiment, a transformer comprising inductors 571 and 572 that is electrically coupled to the main RF line 551 may be used to transform the impedance of a capacitor 555 that is coupled to a switching architecture. Additionally, a switch 570 (e.g., a single pole, single throw (SPST) switch) may be coupled to an electrical path between the capacitor 555 and a transistor 557 (e.g., a high bandgap MOSFET). When the switch 570 is closed, the power source 574 (e.g., a high voltage DC power source) is electrically coupled to the circuit, and when the switch 570 is open, the power source 574 is disconnected from the circuit. In some embodiments, the switch 570 may be operated in unison with the transistor 557. That is, when current passes through the transistor 557, the switch 570 may also be closed in order to connect the power source 574 to the circuit. Such embodiments may allow for rapid switching (e.g., less than 1.0 μs or less than 0.1 μs) while also providing a good on/off ratio. Parasitic elements 573 between the capacitor 555 and the switch 570 are also illustrated for clarity.

Referring now to FIG. 5B, a circuit diagram of a switched shunt capacitor 533 coupled to a main RF line 551 is shown, in accordance with an additional embodiment. The topology of FIG. 5B may be similar to that of FIG. 5A, with the exception of the topology of FIG. 5B using a balanced transformer architecture. The balanced approach may allow for higher capacitance values while also providing symmetrical waveforms.

In an embodiment, the balanced transformer 575 may have an inductor 576 directly coupled to the main RF line 551, and a pair of inductors 577 and 578 may be inductively coupled to the inductor 576. In an embodiment, a first capacitor 555_{A} may be electrically coupled between the inductor 578 and a first transistor 557_{A}, and a second capacitor 555_{B} may be electrically coupled between the inductor 577 and a second transistor 557_{B}. Parasitic elements 573_{A} and 573_{B} are also illustrated for clarity. In an embodiment, a first high-voltage power source 574_{A} is electrically coupled to an electrical path between the first capacitor 555_{A} and the first transistor 557_{A}, and a second high-voltage power source 574_{B} is electrically coupled to an electrical path between the second capacitor 555_{B} and the second transistor 557_{B}. In some embodiments, a switch 570_{A} or 570_{B} may be provided to selectively couple the power sources 574_{A} and 574_{B}, respectively, to the circuit. The switches 570 may be SPST switches similar to those described in greater detail herein.

Thus, embodiments of the present disclosure include systems that include a solid-state impedance match with a multi-stage design that includes switched shunt capacitors arranged in a capacitor bank.

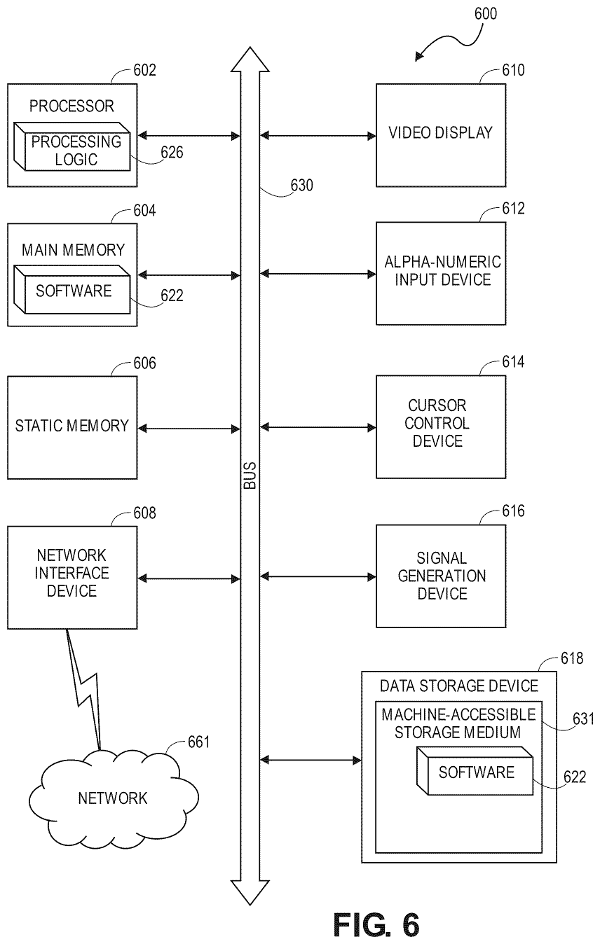

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine.

Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a first trace;
a capacitor electrically coupled to the first trace;
a balanced transformer electrically coupled to the capacitor;
a first transistor and a first diode electrically coupled to a first inductor of the balanced transformer; and
a second transistor and a second diode electrically coupled to a second inductor of the balanced transformer.

2. The apparatus of claim 1, wherein the first transistor and/or the second transistor have bandgaps that are 1.5 eV or higher.

3. The apparatus of claim 1, wherein the first transistor and/or the second transistor comprise SiC or GaN.

4. The apparatus of claim 1, wherein a first grounded capacitor is electrically coupled to a first electrical path between the first transistor and the first diode, and wherein a second grounded capacitor is electrically coupled to a second electrical path between the second transistor and the second diode.

5. The apparatus of claim 1, wherein the capacitor has a capacitance between 5 pF and 5,000 pF.

6. The apparatus of claim 1, further comprising:
a third diode that is in electrical parallel with the first diode; and
a fourth diode that is in electrical parallel with the second diode.

7. An apparatus, comprising:
a board;
a trace on the board, wherein the trace is electrically conductive; and
a plurality of switched shunt capacitors electrically coupled to the trace, wherein the plurality of switched shunt capacitors comprise a plurality of different capacitance values, and wherein each of the plurality of switched shunt capacitors comprises:
a capacitor;
a transformer electrically coupled to the capacitor; and
a transistor electrically coupled to the transformer, wherein the transistor has a bandgap that is 1.5 eV or higher.

8. The apparatus of claim 7, wherein the transformer is a balanced transformer with a first inductor and a second inductor.

9. The apparatus of claim 8, further comprising a second transistor with a bandgap that is 1.5 eV or higher, and wherein the transistor is electrically coupled to the first inductor and the second transistor is electrically coupled to the second inductor.

10. The apparatus of claim 7, wherein the transformer is an auto-transformer that comprises a first inductor and a second inductor.

11. The apparatus of claim 10, wherein the transistor is electrically coupled to an electrical path that is between the first inductor and the second inductor.

12. The apparatus of claim 7, wherein the plurality of different capacitance values comprise two or more values with a form 2ⁿ x, where n is 0 or more and x is greater than 0 pF.

13. The apparatus of claim 7, further comprising a varactor coupled to the board.

14. The apparatus of claim 7, further comprising:
a switch between the transistor and the transformer.

15. The apparatus of claim 14, wherein the switch comprises a single pole, single throw (SPST) switch.

16. The apparatus of claim 14, wherein the switch connects and disconnects a DC power source from an electrical path between the transistor and the transformer.

17. The apparatus of claim 7, wherein the transistor comprise SiC or GaN.

18. An apparatus, comprising:
a first impedance match stage, wherein the first impedance match stage comprises:
a solid state varactor; and
a first switched shunt capacitor bank that comprises a first plurality of individually controllable switched shunt capacitors; and
a second impedance match stage that is electrically coupled to the first impedance match stage, wherein the second impedance match stage comprises a second switch shunt capacitor bank that comprises a second plurality of individually controllable switched shunt capacitors, and wherein each of the first plurality and the second plurality of individually controllable switched shunt capacitors comprises:
a capacitor;
a transformer electrically coupled to the capacitor; and
a transistor electrically coupled to the transformer, wherein the transistor has a bandgap that is 1.5 eV or higher.

19. The apparatus of claim 18, wherein the transformer is a balanced transformer.

20. The apparatus of claim 18, wherein the transformer is an auto-transformer.
